(19) United States
(12) Patent Application Publication
(10) Pub. No.: US 2025/0211409 A1
(43) Pub. Date: Jun. 26, 2025

(54) RADIO FREQUENCY CIRCUIT AND COMMUNICATION DEVICE

(71) Applicant: Murata Manufacturing Co., Ltd., Nagaokakyo-shi (JP)

(72) Inventors: Hidenori OBIYA, Nagaokakyo-shi (JP); Tomohiro SANO, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 19/078,340

(22) Filed: Mar. 13, 2025

Related U.S. Application Data
(63) Continuation of application No. PCT/JP2023/025707, filed on Jul. 12, 2023.

(30) Foreign Application Priority Data
Sep. 16, 2022 (JP) 2022-147860

(51) Int. Cl. H04L 5/14; H03F 3/24; H04B 1/00

(52) U.S. Cl. CPC H04L 5/14; H04B 1/0064; H03F 3/245; H03F 2200/294; H03F 2200/451

(57) ABSTRACT

A radio frequency circuit is configured to simultaneously transfer a signal in a first band and a signal in a second band different from the first band, and includes: a first filter having a passband that includes at least a portion of the first band; a first power amplifier connected to the first filter; a second filter having a passband that includes at least a portion of the second band; a first low-noise amplifier connected to the second filter; and a first band stop filter connected to an output end of the first low-noise amplifier, and having a stopband that includes at least a portion of the first band.

### CROSS-REFERENCE TO RELATED APPLICATIONS

This is a continuation application of PCT International Application No. PCT/JP2023/025707, filed on Jul. 12, 2023, designating the United States of America, which is based on and claims priority to Japanese Patent Application No. 2022-147860, filed on Sep. 16, 2022. The entire disclosures of the above-identified applications, including the specifications, drawings and claims are incorporated herein by reference in their entirety.

### TECHNICAL FIELD

The present disclosure relates to a radio frequency circuit and a communication device.

### BACKGROUND

In recent communication service, communication bands are widened and a plurality of communication bands are simultaneously used, for the purpose of increasing the capacity and the speed of communication.

International Publication WO 2022/024642 discloses a radio frequency module that can simultaneously transfer a received signal in Band A and a transmission signal in Band B and includes a band pass filter having a passband that is Band B, a low-noise amplifier that can amplify signals in Band B, and a band stop filter connected between the band pass filter and the input end of the low-noise amplifier and having a stopband that is a predetermined frequency band that does not overlap Band B. According to this, the band stop filter can remove a noise component in the predetermined frequency band from a received signal in Band B input to the low-noise amplifier, and thus deterioration of reception sensitivity for Band B can be reduced.

### SUMMARY

### Technical Problems

However, as recognized by the present inventor, in the radio frequency module disclosed in International Publication WO 2022/024642, although the band stop filter disposed on the input side of the low-noise amplifier removes a noise component in the predetermined frequency band, the band stop filter also attenuates a weak received signal in Band B. Thus, the signal-to-noise (S/N) ratio of the received signal in Band B may decrease, thus resulting in deterioration of the reception sensitivity.

In view of this, the present disclosure is to address such problems as stated above, and is to provide a radio frequency circuit and a communication device that can reduce deterioration of sensitivity of a received signal transferred simultaneously with a transmission signal.

### Solutions

In order to provide such a radio frequency circuit, a radio frequency circuit according to an aspect of the present disclosure is a radio frequency circuit configured to simultaneously transfer a signal in a first band and a signal in a second band different from the first band, the radio frequency circuit including: a first filter having a passband that includes at least a portion of the first band; a first power amplifier connected to the first filter; a second filter having a passband that includes at least a portion of the second band; a first low-noise amplifier connected to the second filter; and a first band stop filter connected to an output end of the first low-noise amplifier, and having a stopband that includes at least a portion of the first band.

### Advantageous Effects

According to the present disclosure, a radio frequency circuit and a communication device that can reduce deterioration of sensitivity of a received signal transferred simultaneously with a transmission signal can be provided.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a circuit configuration of a radio frequency circuit and a communication device according to an exemplary embodiment.

FIG. 2 qualitatively illustrates a first example of passing characteristics of filters according to the exemplary embodiment.

FIG. 3 qualitatively illustrates a second example of passing characteristics of the filters according to the exemplary embodiment.

FIG. 4 illustrates a circuit configuration of a radio frequency circuit and a communication device according to Variation 1 of the exemplary embodiment.

FIG. 5 illustrates a circuit configuration of a radio frequency circuit and a communication device according to Variation 2 of the exemplary embodiment.

FIG. 6 illustrates a circuit configuration of a radio frequency circuit and a communication device according to Variation 3 of the exemplary embodiment.

### DESCRIPTION OF EMBODIMENTS

In the following, embodiments of the present disclosure are to be described in detail. Note that the embodiments described below each show a general or specific example. The numerical values, shapes, materials, elements, and the arrangement and connection of the elements, for instance, described in the following embodiments are examples, and thus are not intended to limit the present disclosure. Among the elements in the following embodiments and variations, elements not recited in any independent claim are described as optional elements. Furthermore, sizes or a ratio of sizes of elements illustrated in the drawings are not necessarily accurate. In the drawings, the same sign is given to substantially the same configuration, and a redundant description thereof may be omitted or simplified.

In the present disclosure, a term that indicates a relation between elements such as parallel or perpendicular, a term that indicates the shape of an element such as rectangular, and a numerical range do not necessarily have only strict meanings and also cover substantially equivalent ranges that include a difference of about several percent, for example.

In the present disclosure, “being connected” has a meaning including not only the case of being directly connected by a connection terminal and/or a line conductor, but also the case of being electrically connected via another circuit element. The expression “connected between A and B” means being connected between A and B on a path that connects A and B.

In the present disclosure, a “path” means a transfer route that includes, for instance, a line through which a radio frequency signal propagates, an electrode directly connected to the line, and a terminal directly connected to the line or the electrode.

In the present disclosure, a first band (Band A), a second band (Band B), a third band, and a fourth band are intended to mean frequency bands defined in advance by, for instance, a standardizing body (such as the 3rd Generation Partnership Project (3GPP (a registered trademark)) or the Institute of Electrical and Electronics Engineers (IEEE), for example), for a communication system established using radio access technology (RAT). In the present embodiment and the variations, as a communication system, for example, a Long Term Evolution (LTE) system, a 5th Generation (5G) New Radio (NR) system, or a Wireless Local Area Network (WLAN) system, for instance, can be used as a communication system, but the communication system is not limited thereto.

An uplink operating band means a frequency range designated for uplink in each of the above bands. A downlink operating band means a frequency range designated for downlink in each of the above bands.

### Embodiment

### [1 Circuit Configuration of Radio Frequency Circuit 1 and Communication Device 4]

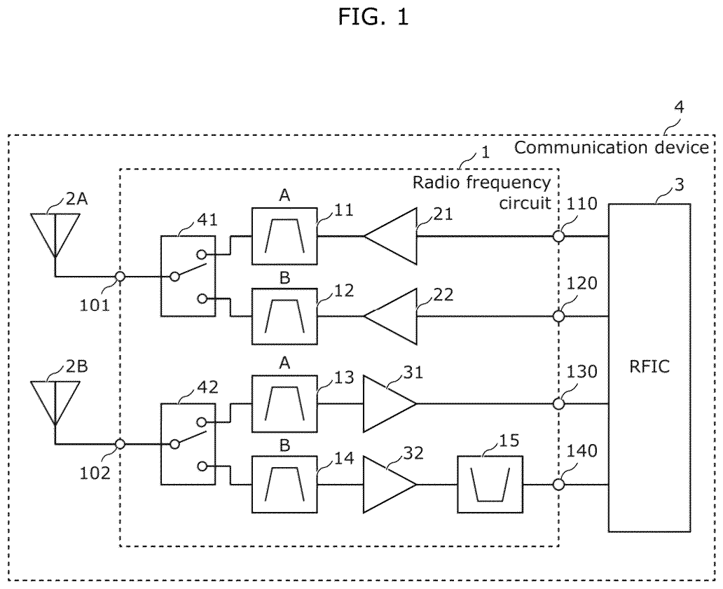

A circuit configuration of radio frequency circuit 1 and communication device 4 according to the present embodiment is to be described with reference to FIG. 1. FIG. 1 illustrates a circuit configuration of radio frequency circuit 1 and communication device 4 according to an exemplary embodiment.

### [1.1 Circuit Configuration of Communication Device 4]

First, a circuit configuration of communication device 4 is to be described. As illustrated in FIG. 1, communication device 4 according to the present embodiment includes radio frequency circuit 1, antennas 2A and 2B, and radio frequency (RF) signal processing circuit (RF integrated circuit (IC)) 3.

Radio frequency circuit 1 transfers radio frequency signals between antennas 2A and 2B and RFIC 3. A detailed circuit configuration of radio frequency circuit 1 is to be described later.

Antenna 2A is connected to antenna connection terminal 101 of radio frequency circuit 1, and transmits a radio frequency signal output by radio frequency circuit 1.

Antenna 2B is connected to antenna connection terminal 102 of radio frequency circuit 1. Antenna 2B receives an external radio frequency signal, and transmits the radio frequency signal to radio frequency circuit 1.

RFIC 3 is an example of a signal processing circuit that processes radio frequency signals. Specifically, RFIC 3 processes radio frequency received signals (hereinafter, referred to as received signals) input through reception paths of radio frequency circuit 1 by, for instance, down-conversion, and outputs received signals generated by processing the received signals to a base band signal processing circuit (BBIC (not illustrated)). Specifically, RFIC 3 processes transmission signals input from the BBIC by, for instance, up-conversion, and outputs radio frequency transmission signals (hereinafter, referred to as transmission signals) generated by processing the transmission signals to transmission paths of radio frequency circuit 1. RFIC 3 includes a controller that controls, for instance, a switch and an amplifier that are included in radio frequency circuit 1. Note that part of or the entire functionality of RFIC 3 as a controller may be provided outside of RFIC 3, and thus may be provided in the BBIC or radio frequency circuit 1, for example.

Note that antennas 2A and 2B are not essential elements of communication device 4 according to the present embodiment.

### [1.2 Circuit Configuration of Radio Frequency Circuit 1]

Next, a circuit configuration of radio frequency circuit 1 is to be described. As illustrated in FIG. 1, radio frequency circuit 1 includes power amplifiers 21 and 22, low-noise amplifiers 31 and 32, filters 11, 12, 13, and 14, band stop filter 15, switches 41 and 42, antenna connection terminals 101 and 102, radio frequency input terminals 110 and 120, and radio frequency output terminals 130 and 140.

Antenna connection terminal 101 is an external connection terminal that radio frequency circuit 1 includes and is connected to antenna 2A. Antenna connection terminal 102 is an external connection terminal that radio frequency circuit 1 includes and is connected to antenna 2B. Radio frequency input terminals 110 and 120 are external connection terminals that radio frequency circuit 1 includes and are terminals through which transmission signals are received from RFIC 3. Radio frequency input terminals 130 and 140 are external connection terminals that radio frequency circuit 1 includes and are terminals through which received signals are output to RFIC 3.

Power amplifier 21 is an example of a first power amplifier. The input end thereof is connected to radio frequency input terminal 110, whereas the output end thereof is connected to filter 11. Power amplifier 22 is an example of a second power amplifier. The input end thereof is connected to radio frequency input terminal 120, whereas the output end thereof is connected to filter 12.

Low-noise amplifier 31 is an example of a second low-noise amplifier. The input end thereof is connected to filter 13, whereas the output end thereof is connected to radio frequency output terminal 130. Low-noise amplifier 32 is an example of a first low-noise amplifier. The input end thereof is connected to filter 14, whereas the output end thereof is connected to radio frequency output terminal 140 via band stop filter 15.

Filter 11 is an example of a first filter, and has a passband that includes at least a portion of the first band. Filter 11 is connected between switch 41 and power amplifier 21.

Filter 12 is an example of a third filter, and has a passband that includes at least a portion of the third band. Filter 12 is connected between switch 41 and power amplifier 22.

Filter 13 is an example of a fourth filter, and has a passband that includes at least a portion of the fourth band. Filter 13 is connected between switch 42 and low-noise amplifier 31.

Filter 14 is an example of a second filter, and has a passband that includes at least a portion of the second band different from the first band. Filter 14 is connected between switch 42 and low-noise amplifier 32.

Band stop filter 15 is an example of a first band stop filter, and has a stopband that includes at least a portion of the first band. Band stop filter 15 is connected between the output end of low-noise amplifier 32 and radio frequency output terminal 140.

Switch 41 includes a first common terminal, a first selection terminal, and a second selection terminal. Switch 41 switches between connection and disconnection between the first common terminal and the first selection terminal, and switches between connection and disconnection between the first common terminal and the second selection terminal. The first common terminal is connected to antenna connection terminal 101, the first selection terminal is connected to filter 11, and the second selection terminal is connected to filter 12.

Switch 42 includes a second common terminal, a third selection terminal, and a fourth selection terminal. Switch 42 switches between connection and disconnection between the second common terminal and the third selection terminal, and switches between connection and disconnection between the second common terminal and the fourth selection terminal. The second common terminal is connected to antenna connection terminal 102, the third selection terminal is connected to filter 13, and the fourth selection terminal is connected to filter 14.

With the above configuration, radio frequency circuit 1 can simultaneously transfer a transmission signal in the first band through radio frequency input terminal 110, power amplifier 21, filter 11, switch 41, and antenna connection terminal 101 and a received signal in the second band through antenna connection terminal 102, switch 42, filter 14, low-noise amplifier 32, band stop filter 15, and radio frequency output terminal 140.

Furthermore, radio frequency circuit 1 can simultaneously transfer a transmission signal in the third band through radio frequency input terminal 120, power amplifier 22, filter 12, switch 41, and antenna connection terminal 101 and a received signal in the fourth band through antenna connection terminal 102, switch 42, filter 13, low-noise amplifier 31, and radio frequency output terminal 130.

Furthermore, radio frequency circuit 1 can simultaneously transfer a transmission signal in the first band through radio frequency input terminal 110, power amplifier 21, filter 11, switch 41, and antenna connection terminal 101 and a transmission signal in the third band through radio frequency input terminal 120, power amplifier 22, filter 12, switch 41, and antenna connection terminal 101.

Furthermore, radio frequency circuit 1 can simultaneously transfer a received signal in the second band through antenna connection terminal 102, switch 42, filter 14, low-noise amplifier 32, band stop filter 15, and radio frequency output terminal 140 and a received signal in the fourth band through antenna connection terminal 102, switch 42, filter 13, low-noise amplifier 31, and radio frequency output terminal 130.

In a state in which a transmission signal in the first band and a received signal in the second band are simultaneously transferred, the transmission signal in the first band through radio frequency input terminal 110, power amplifier 21, filter 11, switch 41, and antenna connection terminal 101 may leak into a reception path connecting antenna connection terminal 102, switch 42, filter 14, and low-noise amplifier 32. In this case, under a condition that a leaky wave of the transmission signal in the first band is superimposed on the received signal in the second band being transferred through the reception path, the S/N ratio of the received signal in the second band decreases and signal distortion occurs in RFIC 3. As a result, reception sensitivity for the second band may deteriorate. Deterioration of reception sensitivity for the second band becomes problematic in particular in a case in which a leaky wave of a transmission signal having a wide bandwidth enters RFIC 3 at a high level from the reception path for the second band.

In contrast, according to the above configuration of radio frequency circuit 1 according to the present embodiment, band stop filter 15 having a stopband that is at least a portion of the first band is disposed on the output side of low-noise amplifier 32 (immediately before RFIC 3), and thus a leaky wave of a transmission signal in the first band being transferred through the reception path for the second band can be reduced. Accordingly, a decrease in the S/N ratio of a received signal in the second band can be reduced, and signal distortion in RFIC 3 can be reduced. Thus, deterioration of reception sensitivity for the second band can be reduced. Band stop filter 15 has a stopband that is the first band, and thus the filter structure thereof can be decreased in size and simplified as compared with a band pass filter having a passband that is the second band and an attenuation band that is other than the second band.

In a case in which the band stop filter is disposed on the input side of low-noise amplifier 32, a leaky wave of a transmission signal in the first band can be reduced, yet the band stop filter also attenuates a weak received signal in the second band before being amplified by low-noise amplifier 32. Accordingly, the S/N ratio of a received signal in the second band decreases, and the noise figure increases. In contrast, in radio frequency circuit 1 according to the present embodiment, since band stop filter 15 is disposed on the output side of low-noise amplifier 32, a leaky wave of a transmission signal in the first band is reduced in a state in which a received signal in the second band is amplified by low-noise amplifier 32. Accordingly, a decrease in the S/N ratio of a received signal in the second band can be effectively reduced. Hence, as compared with a configuration in which the band stop filter is disposed on the input side of low-noise amplifier 32, deterioration of reception sensitivity for the second band can be effectively reduced.

Note that in the present embodiment, filters 11 and 12 are connected to antenna 2A, and filters 13 and 14 are connected to antenna 2B. Thus, filter 11 and filter 14 are connected to different antennas.

According to this, a transmission path for the first band that includes filter 11 and a reception path for the second band that includes filter 14 can be highly isolated from each other. Thus, leakage of a transmission signal in the first band to the reception path for the second band that includes filter 14 can be reduced.

Note that in radio frequency circuit 1 according to the present embodiment, the first band, the second band, the third band, and the fourth band are bands for time division duplex (TDD). The first band and the fourth band are the same band, which is Band A, and the second band and the third band are the same, which is Band B.

Band A (the first band and the fourth band) is, for example, band B40 for LTE or band n40 for 5G NR (2300 MHz to 2400 MHZ), and Band B (the second band and the third band) is, for example, band B41 for LTE or band n41 for 5G NR (2496 MHZ to 2690 MHz).

Band A (the first band and the fourth band) may be, for example, one of band n77 (3300 MHz to 4200 MHZ), n78 (3300 MHz to 3800 MHZ), or n79 (4400 MHz to 5000 MHz) for 5G NR, and Band B (the second band and the third band) may be, for example, a different one of band n77, n78, or n79 for 5G NR.

Band A (the first band and the fourth band) may be, for example, one of a first frequency range defined by 5150 MHz to 5925 MHZ (band n46 for 5G NR, for example), a second frequency range defined by 5925 MHz to 7125 MHZ (band n96 or n106 for 5G NR, for example), a third frequency range defined by 5925 MHz to 6425 MHz (band n102 for 5G NR, for example), or a fourth frequency range defined by 6425 MHz to 7125 MHz (band n104 for 5G NR, for example), and Band B (the second band and the third band) may be a different one of the first frequency range, the second frequency range, the third frequency range, or the fourth frequency range, for example.

Note that a signal in Band A and a signal in Band B are transferred asynchronously, under a condition that Band A (the first band and the fourth band) and Band B (the second band and the third band) are bands for TDD. Thus, not only simultaneous transfer of a transmission signal in Band A and a transmission signal in Band B and simultaneous transfer of a received signal in Band A and a received signal in Band B, but also simultaneous transfer of a transmission signal in Band A and a received signal in Band B and simultaneous transfer of a received signal in Band A and a transmission signal in Band B are conducted.

In radio frequency circuit 1 according to the present embodiment, the first band, the second band, the third band, and the fourth band may be bands for frequency division duplex (FDD). In this case, the first band and the fourth band may be the same band, which is Band A, and the second band and the third band may be the same band, which is Band B.

In this case, Band A (the first band and the fourth band) may be a band selected from among, for example, bands B1, B2, B3, B25, and B74 for LTE and band n1 (uplink operating band: 1920 MHz to 1980 MHz, downlink operating band: 2110 MHz to 2170 MHz), n2 (uplink operating band: 1850 MHz to 1910 MHz, downlink operating band: 1930 MHz to 1990 MHZ), n3 (uplink operating band: 1710 MHz to 1785 MHz, downlink operating band: 1805 MHz to 1880 MHz), n25 (uplink operating band: 1850 MHz to 1915 MHz, downlink operating band: 1930 MHz to 1995 MHz), and n74 (uplink operating band: 1427 MHz to 1470 MHz, downlink operating band: 1475 MHz to 1518 MHz) for 5G NR, and Band B (the second band and the third band) may be, for example, a different band selected from among bands B1, B2, B3, B25, and B74 for LTE and bands n1, n2, n3, n25, and n74 for 5G NR.

Furthermore, Band A (the first band and the fourth band) may be a band selected from among, for example, bands B8, B12, B13, B20, B26, B71, and B85 for LTE and band n8 (uplink operating band: 880 MHz to 915 MHz, downlink operating band: 925 MHz to 960 MHZ), n12 (uplink operating band: 699 MHz to 716 MHZ, downlink operating band: 729 MHz to 746 MHZ), n13 (uplink operating band: 777 MHz to 787 MHz, downlink operating band: 746 MHz to 756 MHZ), n20 (uplink operating band: 832 MHz to 862 MHz, downlink operating band: 791 MHz to 821 MHz), n26 (uplink operating band: 814 MHz to 849 MHz, downlink operating band: 859 MHz to 894 MHZ), n71 (uplink operating band: 663 MHz to 698 MHz, downlink operating band: 617 MHz to 652 MHZ) and n85 (uplink operating band: 698 MHz to 716 MHz, downlink operating band: 728 MHz to 746 MHz) for 5G NR, and Band B (the second band and the third band) may be a different band selected from among, for example, bands B8, B12, B13, B20, B26, B71, and B85 for LTE and bands n8, n12, n13, n20, n26, n71, and n85 for 5G NR.

One of Band A (the first band and the fourth band) or Band B (the second band and the third band) may be, for example, band B22 for LTE (uplink operating band: 3410 MHz to 3490 MHz, downlink operating band: 3510 MHz to 3590 MHz).

As described above, a combination of the first band and the second band applies to both the TDD method and the FDD method, and is applied to (1) the case in which one of the first band or the second band is a band for LTE and the other of the first band or the second band is a band for 5G NR (ENDC), (2) the case in which both the first band and the second band are bands for LTE, and (3) the case in which both the first band and the second band are bands for 5G NR.

Note that in radio frequency circuit 1 according to the present embodiment, under a condition that a transmission signal in the first band corresponds to a transmission signal in a high power class (Power Class 2 or higher), a leaky wave in the first band that leaks into the reception path for the second band increases, and thus reduction of a leaky wave by band stop filter 15 has a significant meaning.

Note that a power class is a classification of output power of user equipment (UE) defined based on, for instance, a maximum output power, and a smaller value of a power class indicates that a higher output power is allowed. For example, according to the 3GPP (a registered trademark), the maximum output power allowed in Power Class 1 is 31 dBm, the maximum output power allowed in Power Class 1.5 is 29 dBm, and the maximum output power allowed in Power Class 2 is 26 dBm, and the maximum output power allowed in Power Class 3 is 23 dBm.

In radio frequency circuit 1 according to the present embodiment, under a condition that the second band is a band for 5G NR, an S/N ratio of a received signal is to be often higher than the S/N ratio for LTE, and thus reduction of a leaky wave by band stop filter 15 has a significant meaning.

Note that in a case in which the first band and the second band are bands of 3 GHz or higher, band stop filter 15 may be an LC filter that includes an inductor and a capacitor.

According to this, a low-loss band stop filter can be acquired by using a simplified filter structure.

The inductor and the capacitor included in the LC filter may be integrated passive devices (IPDs) provided in or on a semiconductor substrate. According to this, the size of band stop filter 15 can be reduced.

Radio frequency circuit 1 may include power amplifiers 21 and 22, low-noise amplifiers 31 and 32, and a dielectric substrate in or on which filters 11 to 14 are disposed, and the inductor and the capacitor included in the LC filter may be provided in or on the dielectric substrate. According to this, the size of radio frequency circuit 1 can be reduced.

The inductor and the capacitor included in the LC filter may be surface-mounted elements disposed in or on the dielectric substrate. According to this, passing characteristics of band stop filter 15 can be improved by the inductor and the capacitor having high quality factors (Q factors).

Note that in radio frequency circuit 1 according to the present embodiment, power amplifier 21, low-noise amplifier 32, filters 11 and 14, and band stop filter 15 are essential elements, and power amplifier 22, low-noise amplifier 31, filters 12 and 13, and switches 41 and 42 may not be included.

### [1.3 Filter Characteristics of Radio Frequency Circuit 1]

Next, passing characteristics of the filters included in radio frequency circuit 1 are to be described.

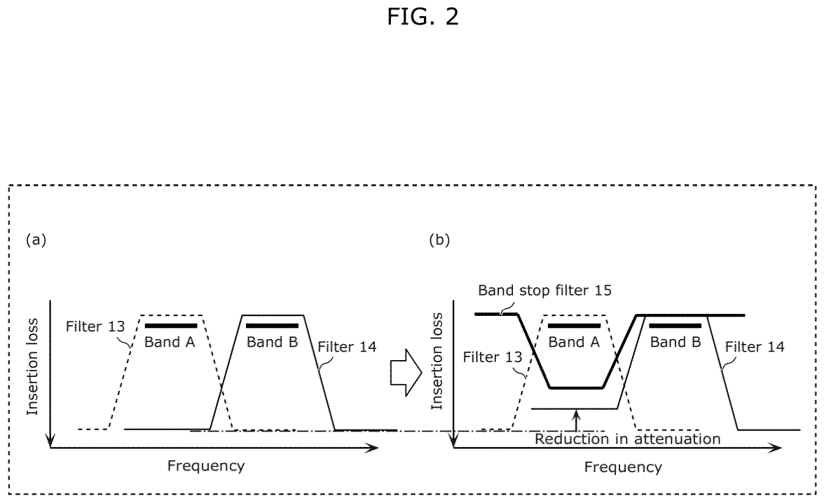

FIG. 2 qualitatively illustrates a first example of passing characteristics of the filters according to the exemplary embodiment. Part (a) of FIG. 2 illustrates qualitative passing characteristics of filters 13 and 14 under a condition that radio frequency circuit 1 does not include band stop filter 15. Part (b) of FIG. 2 illustrates qualitative passing characteristics of filters 13, 14, and 15 in radio frequency circuit 1 that includes band stop filter 15.

As illustrated in (a) of FIG. 2, under a condition that band stop filter 15 is not disposed, a necessary attenuation of a signal in the first band (Band A) for a reception path for the second band is determined by an attenuation of filter 14.

In contrast, in radio frequency circuit 1 that includes band stop filter 15, filter 14 and band stop filter 15 are cascaded on the reception path for the second band with low-noise amplifier 32 being provided therebetween, and thus a necessary attenuation of a signal in the first band (Band A) for the reception path for the second band is a result of adding the attenuation of filter 14 and the attenuation of band stop filter 15. Thus, as illustrated in (b) of FIG. 2, the attenuation of a signal in the first band of filter 14 can be reduced by the attenuation of band stop filter 15. Accordingly, with filter 14, insertion loss of a signal in the second band (Band B) can be reduced along with reduction in the attenuation of a signal in the first band. Thus, a noise figure of a received signal in the second band can be reduced by reducing insertion loss of filter 14 disposed on the input side of low-noise amplifier 32.

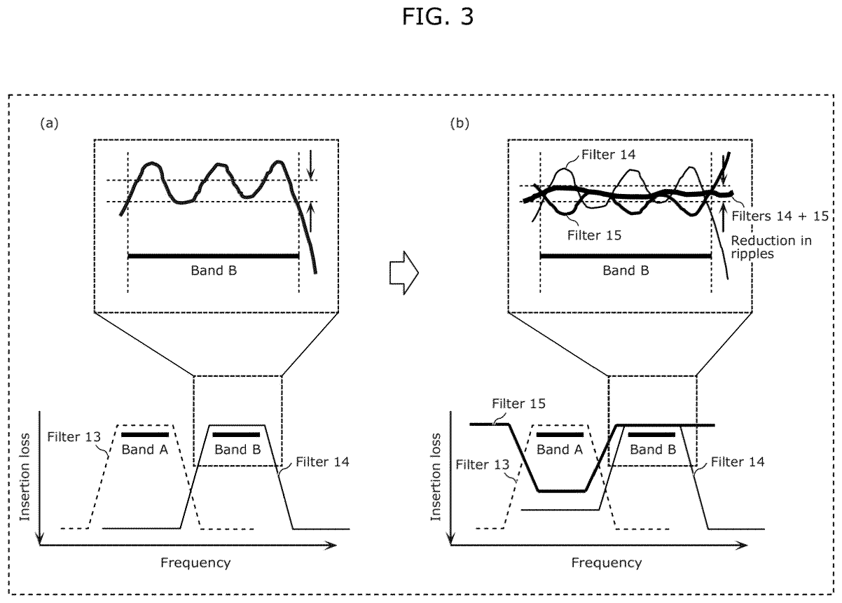

FIG. 3 qualitatively illustrates a second example of passing characteristics of the filters according to the exemplary embodiment. Part (a) of FIG. 3 illustrates qualitative passing characteristics of filters 13 and 14 under a condition that radio frequency circuit 1 does not include band stop filter 15. Part (b) of FIG. 3 illustrates qualitative passing characteristics of filters 13, 14, and 15 in radio frequency circuit 1 that includes band stop filter 15.

As illustrated in (a) of FIG. 3, under a condition that band stop filter 15 is not provided, certain in-band ripples occur in the passband (Band B) of filter 14 disposed on the reception path for the second band.

In contrast, in radio frequency circuit 1 that includes band stop filter 15, filter 14 and band stop filter 15 are cascaded on the reception path for the second band with low-noise amplifier 32 being provided therebetween, and thus as illustrated in (b) of FIG. 3, by making frequency dependency of insertion loss of a signal in Band B of band stop filter 15 different from the frequency dependency of insertion loss of a signal in Band B of filter 14, in-band ripples in Band B (the second band) of the reception path for the second band can be reduced. More specifically, by inverting fluctuating characteristics of insertion loss of a signal in Band B of band stop filter 15 with respect to fluctuating characteristics of insertion loss of a signal in Band B of filter 14, in-band ripples in Band B (the second band) of the reception path for the second band can be reduced.

Note that in order to reduce in-band ripples in Band B of filter 14, from the viewpoint that a design parameter for providing a passband of Band B is less constrained, a band stop filter is more suitable for a filter cascaded with filter 14 than a band pass filter.

Note that a band stop filter in the present embodiment is defined as below. Specifically, the band stop filter has a stopband, a low-frequency passband having a range of frequencies lower than that of the stopband, and a high-frequency passband having a range of frequencies higher than that of the stopband, and the bandwidth of the stopband is narrower than the bandwidth of the low-frequency passband and is narrower than the bandwidth of the high-frequency passband. Note that the stopband has insertion loss of 5 dB or higher, and the low-frequency passband and the high-frequency passband each have insertion loss less than 5 dB.

### [1.4 Circuit Configuration of Radio Frequency Circuit 1A According to Variation 1]

Next, a circuit configuration of radio frequency circuit 1A according to Variation 1 is to be described.

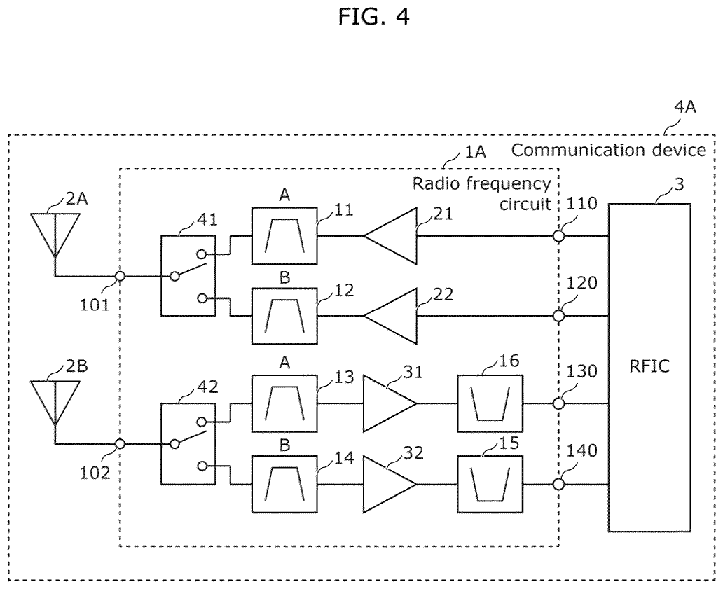

FIG. 4 illustrates a circuit configuration of radio frequency circuit 1A and communication device 4A according to Variation 1 of the exemplary embodiment. Communication device 4A according to this variation includes radio frequency circuit 1A, antennas 2A and 2B, and RFIC 3. Communication device 4A according to this variation is different from communication device 4 according to the embodiment only in radio frequency circuit 1A. In the following, communication device 4A according to this variation is to be described focusing on radio frequency circuit 1A configured differently from communication device 4 according to the embodiment.

As illustrated in FIG. 4, radio frequency circuit 1A includes power amplifiers 21 and 22, low-noise amplifiers 31 and 32, filters 11, 12, 13, and 14, band stop filters 15 and 16, switches 41 and 42, antenna connection terminals 101 and 102, radio frequency input terminals 110 and 120, and radio frequency output terminals 130 and 140.

Radio frequency circuit 1A according to this vitiation is different from radio frequency circuit 1 according to the embodiment only in that band stop filter 16 is added. In the following, the description of the configuration of radio frequency circuit 1A according to this variation which is the same as the configuration of radio frequency circuit 1 according to the embodiment is omitted, and a configuration of radio frequency circuit 1A different therefrom is mainly described.

Low-noise amplifier 31 is an example of a second low-noise amplifier. The input end thereof is connected to filter 13, whereas the output end thereof is connected to radio frequency output terminal 130 via band stop filter 16. Low-noise amplifier 32 is an example of a first low-noise amplifier. The input end thereof is connected to filter 14, whereas the output end thereof is connected to radio frequency output terminal 140 via band stop filter 15.

Band stop filter 16 is an example of a second band stop filter, and has a stopband that includes at least a portion of the third band. Band stop filter 16 is connected between the output end of low-noise amplifier 31 and radio frequency output terminal 130.

With the above configuration, radio frequency circuit 1A can simultaneously transfer a transmission signal in the first band through radio frequency input terminal 110, power amplifier 21, filter 11, switch 41, and antenna connection terminal 101 and a received signal in the second band through antenna connection terminal 102, switch 42, filter 14, low-noise amplifier 32, band stop filter 15, and radio frequency output terminal 140.

Furthermore, radio frequency circuit 1A can simultaneously transfer a transmission signal in the third band through radio frequency input terminal 120, power amplifier 22, filter 12, switch 41, and antenna connection terminal 101 and a received signal in the fourth band through antenna connection terminal 102, switch 42, filter 13, low-noise amplifier 31, and radio frequency output terminal 130.

In a state in which a transmission signal in the third band and a received signal in the fourth band are simultaneously transferred, the transmission signal in the third band through radio frequency input terminal 120, power amplifier 22, filter 12, switch 41, and antenna connection terminal 101 may leak into a reception path connecting antenna connection terminal 102, switch 42, filter 13, and low-noise amplifier 31. In this case, under a condition that a leaky wave of the transmission signal in the third band is superimposed on the received signal in the fourth band being transferred through the reception path, the S/N ratio of the received signal in the fourth band decreases and signal distortion occurs in RFIC 3. As a result, reception sensitivity for the fourth band may deteriorate. Deterioration of reception sensitivity for the fourth band becomes problematic in particular in a case in which a leaky wave of a transmission signal having a wide bandwidth enters at a high level from the reception path for the fourth band.

In contrast, according to the above configuration of radio frequency circuit 1A according to this variation, band stop filter 16 having a stopband that is at least a portion of the third band is disposed on the output side of low-noise amplifier 31 (immediately before RFIC 3), and thus a leaky wave of a transmission signal in the third band being transferred through the reception path for the fourth band can be reduced. Accordingly, a decrease in the S/N ratio of a received signal in the fourth band can be reduced, and signal distortion in RFIC 3 can be reduced. Thus, deterioration of reception sensitivity for the fourth band can be reduced. Band stop filter 16 has a stopband that is the third band, and thus the filter structure thereof can be decreased in size and simplified as compared with a band pass filter having a passband that is the fourth band and an attenuation band that is other than the fourth band.

In a case in which the band stop filter is disposed on the input side of low-noise amplifier 31, a leaky wave of a transmission signal in the third band can be reduced, yet the band stop filter also attenuates a weak received signal in the fourth band before being amplified by low-noise amplifier 31. Accordingly, the S/N ratio of a received signal in the fourth band decreases, and the noise figure increases. In contrast, in radio frequency circuit 1A according to this variation, since band stop filter 16 is disposed on the output side of low-noise amplifier 31, a leaky wave of a transmission signal in the third band is reduced in a state in which a received signal in the fourth band is amplified by low-noise amplifier 31. Accordingly, a decrease in the S/N ratio of a received signal in the fourth band can be effectively reduced. Hence, as compared with a configuration in which the band stop filter is disposed on the input side of low-noise amplifier 31, deterioration of reception sensitivity for the fourth band can be effectively reduced.

Thus, in radio frequency circuit 1A according to this variation, band stop filter 15 can reduce a decrease in the S/N ratio of a received signal in the second band and deterioration of reception sensitivity for the second band, and furthermore, band stop filter 16 can reduce a decrease in the S/N ratio of a received signal in the fourth band and deterioration of reception sensitivity for the fourth band.

Note that in radio frequency circuit 1A according to this variation, the first band, the second band, the third band, and the fourth band are bands for TDD. The first band and the fourth are the same band, which is Band A, and the second band and the third band are the same band, which is Band B.

In radio frequency circuit 1A according to this variation, the first band, the second band, the third band, and the fourth band may be bands for FDD. In this case, the first band and the fourth band may be the same band, which is Band A, and the second band and the third band may be the same band, which is Band B.

Note that in a case in which the first band and the second band are bands of 3 GHz or higher, band stop filter 16 may be an LC filter that includes an inductor and a capacitor.

According to this, a low-loss band stop filter can be acquired by using a simplified filter structure.

The inductor and the capacitor included in the LC filter may be intelligent power devices (IPDs) provided in or on a semiconductor substrate. According to this, the size of band stop filter 16 can be reduced.

Radio frequency circuit 1A may include power amplifiers 21 and 22, low-noise amplifiers 31 and 32, and a dielectric substrate in or on which filters 11 to 14 are disposed, and the inductor and the capacitor included in the LC filter may be provided in or on the dielectric substrate. According to this, the size of radio frequency circuit 1A can be reduced.

The inductor and the capacitor included in the LC filter may be surface-mounted elements disposed in or on the dielectric substrate. According to this, passing characteristics of band stop filter 16 can be improved by the inductor and the capacitor having high Q factors.

### [1.5 Circuit Configuration of Radio Frequency Circuit 1B According to Variation 2]

Next, a circuit configuration of radio frequency circuit 1B according to Variation 2 is to be described.

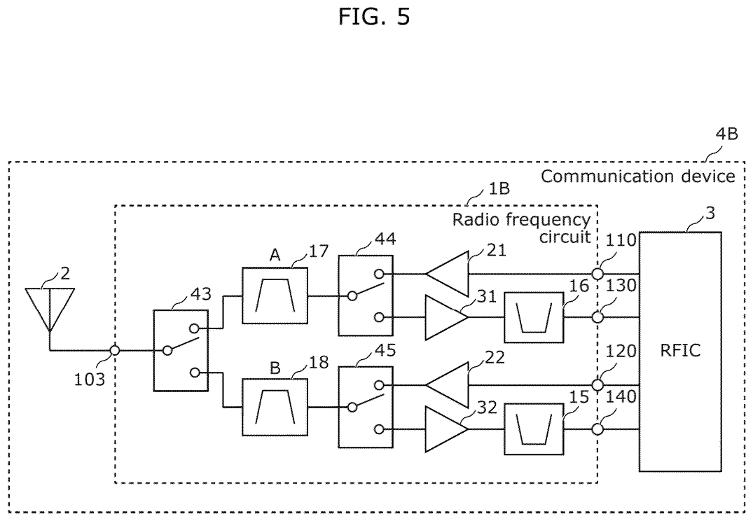

FIG. 5 illustrates a circuit configuration of radio frequency circuit 1B and communication device 4B according to Variation 2 of the exemplary embodiment. Communication device 4B according to this variation includes radio frequency circuit 1B, antenna 2, and RFIC 3. Communication device 4B according to this variation is different from communication device 4 according to the embodiment in the configuration of the antenna and radio frequency circuit 1B. In the following, communication device 4B according to this variation is to be described focusing on antenna 2 and radio frequency circuit 1B that are configured differently from those of communication device 4 according to the embodiment.

As illustrated in FIG. 5, radio frequency circuit 1B includes power amplifiers 21 and 22, low-noise amplifiers 31 and 32, filters 17 and 18, band stop filters 15 and 16, switches 43, 44, and 45, antenna connection terminal 103, radio frequency input terminals 110 and 120, and radio frequency output terminals 130 and 140.

Antenna connection terminal 103 is connected to antenna 2. Radio frequency input terminals 110 and 120 are terminals through which transmission signals are received from RFIC 3. Radio frequency output terminals 130 and 140 are terminals through which received signals are output to RFIC 3.

Power amplifier 21 is an example of a first power amplifier. The input end thereof is connected to radio frequency input terminal 110, whereas the output end thereof is connected to filter 17 via switch 44. Power amplifier 22 is an example of a third power amplifier. The input end thereof is connected to radio frequency input terminal 120, whereas the output end thereof is connected to filter 18 via switch 45.

Low-noise amplifier 31 is an example of a third low-noise amplifier. The input end thereof is connected to filter 17 via switch 44, whereas the output end thereof is connected to radio frequency output terminal 130 via band stop filter 16. Low-noise amplifier 32 is an example of a first low-noise amplifier. The input end thereof is connected to filter 18 via switch 45, whereas the output end thereof is connected to radio frequency output terminal 140 via band stop filter 15.

Filter 17 is an example of a first filter, and has a passband that includes at least a portion of the first band (Band A). Filter 17 is connected between switch 43 and switch 44.

Filter 18 is an example of a second filter, and has a passband that includes at least a portion of the second band (Band B). Filter 18 is connected between switch 43 and switch 45.

Band stop filter 15 is an example of a first band stop filter, and has a stopband that includes at least a portion of the first band. Band stop filter 15 is connected between the output end of low-noise amplifier 32 and radio frequency output terminal 140.

Band stop filter 16 is an example of a third band stop filter, and has a stopband that includes at least a portion of the second band. Band stop filter 16 is connected between the output end of low-noise amplifier 31 and radio frequency output terminal 130.

Switch 43 includes one common terminal and two selection terminals. Switch 43 switches between connection and disconnection between the common terminal and one of the selection terminals and switches between connection and disconnection between the common terminal and the other of the selection terminals. The common terminal is connected to antenna connection terminal 103. One of the selection terminals is connected to filter 17, and the other of the selection terminals is connected to filter 18.

Switch 44 is an example of a first switch, and is connected between (i) filter 17 and (ii) power amplifier 21 and low-noise amplifier 31. Switch 44 includes one common terminal and two selection terminals. Switch 44 switches connection of the common terminal between one of the selection terminals and the other of the selection terminals. The common terminal is connected to filter 17. One of the selection terminals is connected to the output end of power amplifier 21, and the other of the selection terminals is connected to the input end of low-noise amplifier 31.

Switch 45 is an example of a second switch, and is connected between (i) filter 18 and (ii) power amplifier 22 and low-noise amplifier 32. Switch 45 includes one common terminal and two selection terminals. Switch 45 switches connection of the common terminal between one of the selection terminals and the other of the selection terminals. The common terminal is connected to filter 18. One of the selection terminals is connected to the output end of power amplifier 22, and the other of the selection terminals is connected to the input end of low-noise amplifier 32.

In radio frequency circuit 1B according to this variation, the first band (Band A) and the second band (Band B) are bands for TDD.

With the above configuration, radio frequency circuit 1B exclusively transfers a transmission signal in the first band or exclusively transfers a received signal in the first band by switching made by switch 44, and exclusively transfers a transmission signal in the second band or exclusively transfers a received signal in the second band by switching made by switch 45.

Radio frequency circuit 1B can simultaneously transfer a transmission signal in the first band through radio frequency input terminal 110, power amplifier 21, switch 44, filter 17, switch 43, and antenna connection terminal 103 and a received signal in the second band through antenna connection terminal 103, switch 43, filter 18, switch 45, low-noise amplifier 32, band stop filter 15, and radio frequency output terminal 140.

Radio frequency circuit 1B can simultaneously transfer a transmission signal in the second band through radio frequency input terminal 120, power amplifier 22, switch 45, filter 18, switch 43, and antenna connection terminal 103 and a received signal in the first band through antenna connection terminal 103, switch 43, filter 17, switch 44, low-noise amplifier 31, band stop filter 16, and radio frequency output terminal 130.

Furthermore, radio frequency circuit 1B can simultaneously transfer a transmission signal in the first band through radio frequency input terminal 110, power amplifier 21, switch 44, filter 17, switch 43, and antenna connection terminal 103 and a transmission signal in the second band through radio frequency input terminal 120, power amplifier 22, switch 45, filter 18, switch 43, and antenna connection terminal 103.

Radio frequency circuit 1B can simultaneously transfer a received signal in the first band through antenna connection terminal 103, switch 43, filter 17, switch 44, low-noise amplifier 31, band stop filter 16, and radio frequency output terminal 130 and a received signal in the second band through antenna connection terminal 103, switch 43, filter 18, switch 45, low-noise amplifier 32, band stop filter 15, and radio frequency output terminal 140.

With the above configuration of radio frequency circuit 1B according to this variation, band stop filter 15 having a stopband that is at least a portion of the first band is disposed on the output side of low-noise amplifier 32 (immediately before RFIC 3), and thus a leaky wave of a transmission signal in the first band being transferred through the reception path for the second band can be reduced. Accordingly, a decrease in the S/N ratio of a received signal in the second band can be reduced, and signal distortion in RFIC 3 can be reduced. Thus, deterioration of reception sensitivity for the second band can be reduced. Band stop filter 15 has a stopband that is the first band, and thus the filter structure thereof can be decreased in size and simplified as compared with a band pass filter having a passband that is the second band and an attenuation band that is other than the second band.

In a case in which the band stop filter is disposed on the input side of low-noise amplifier 32, a leaky wave of a transmission signal in the first band can be reduced, yet the band stop filter also attenuates a weak received signal in the second band before being amplified by low-noise amplifier 32. Accordingly, the S/N ratio of a received signal in the second band decreases, and the noise figure increases. In contrast, in radio frequency circuit 1B according to this variation, since band stop filter 15 is disposed on the output side of low-noise amplifier 32, a leaky wave of a transmission signal in the first band is reduced in a state in which a received signal in the second band is amplified by low-noise amplifier 32. Accordingly, a decrease in the S/N ratio of a received signal in the second band can be effectively reduced. Hence, as compared with a configuration in which the band stop filter is disposed on the input side of low-noise amplifier 32, deterioration of reception sensitivity for the second band can be effectively reduced.

Furthermore, band stop filter 16 having a stopband that is at least a portion of the second band is disposed on the output side of low-noise amplifier 31 (immediately before RFIC 3), and thus a leaky wave of a transmission signal in the second band being transferred through the reception path for the first band can be reduced. Accordingly, a decrease in the S/N ratio of a received signal in the first band can be reduced, and signal distortion in RFIC 3 can be reduced. Thus, deterioration of reception sensitivity for the first band can be reduced. Band stop filter 16 has a stopband that is the second band, and thus the filter structure thereof can be decreased in size and simplified as compared with a band pass filter having a passband that is the first band and an attenuation band that is other than the first band.

In a case in which the band stop filter is disposed on the input side of low-noise amplifier 31, a leaky wave of a transmission signal in the second band can be reduced, yet the band stop filter also attenuates a weak received signal in the first band before being amplified by low-noise amplifier 31. Accordingly, the S/N ratio of a received signal in the first band decreases, and the noise figure increases. In contrast, in radio frequency circuit 1B according to this variation, since band stop filter 16 is disposed on the output side of low-noise amplifier 31, a leaky wave of a transmission signal in the second band is reduced in a state in which a received signal in the first band is amplified by low-noise amplifier 31. Accordingly, a decrease in the S/N ratio of a received signal in the first band can be effectively reduced. Hence, as compared with a configuration in which the band stop filter is disposed on the input side of low-noise amplifier 31, deterioration of reception sensitivity for the first band can be effectively reduced.

Note that in radio frequency circuit 1B according to this variation, one of band stop filter 15 or band stop filter 16 may not be included.

### [1.6 Circuit Configuration of Radio Frequency Circuit 1C According to Variation 3]

Next, a circuit configuration of radio frequency circuit 1C according to Variation 3 is to be described.

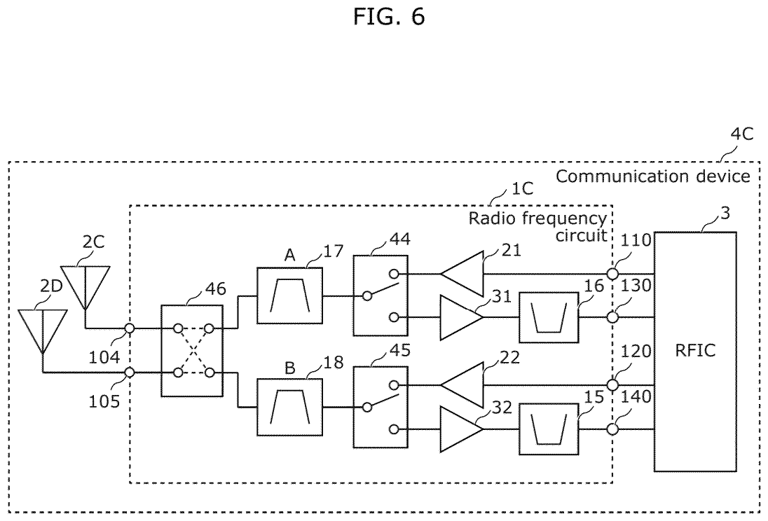

FIG. 6 illustrates a circuit configuration of radio frequency circuit 1C and communication device 4C according to Variation 3 of the exemplary embodiment. Communication device 4C according to this variation includes radio frequency circuit 1C, antennas 2C and 2D, and RFIC 3. Communication device 4C according to this variation is different from communication device 4B according to Variation 2 in the configuration of the antennas and radio frequency circuit 1C. In the following, communication device 4C according to this variation is to be described focusing on antennas 2C and 2D and radio frequency circuit 1C that are configured differently from those of communication device 4B according to Variation 2.

Antenna 2C is connected to antenna connection terminal 104 of radio frequency circuit 1C. Antenna 2C transmits a radio frequency signal output from radio frequency circuit 1C, receives an external radio frequency signal, and outputs the signal to radio frequency circuit 1C.

Antenna 2D is connected to antenna connection terminal 105 of radio frequency circuit 1C. Antenna 2D transmits a radio frequency signal output from radio frequency circuit 1C, receives an external radio frequency signal, and outputs the signal to radio frequency circuit 1C.

As illustrated in FIG. 6, radio frequency circuit 1C includes power amplifiers 21 and 22, low-noise amplifiers 31 and 32, filters 17 and 18, band stop filters 15 and 16, switches 44, 45, and 46, antenna connection terminals 104 and 105, radio frequency input terminals 110 and 120, and radio frequency output terminals 130 and 140.

Radio frequency circuit 1C according to this variation is different from radio frequency circuit 1B according to Variation 2 only in the configuration of switch 46 and antenna connection terminals 104 and 105. In the following, the description of the configuration of radio frequency circuit 1C according to this variation which is the same as the configuration of radio frequency circuit 1B according to Variation 2 is omitted, and a configuration of radio frequency circuit 1C different therefrom is mainly described.

Antenna connection terminal 104 is connected to antenna 2C. Antenna connection terminal 105 is connected to antenna 2D.

Switch 46 includes a first common terminal, a second common terminal, a first selection terminal, and a second selection terminal. Switch 46 exclusively switches between (1) connection of the first common terminal and the first selection terminal and connection of the second common terminal and the second selection terminal and (2) connection of the first common terminal and the second selection terminal and connection of the second common terminal and the first selection terminal. The first common terminal is connected to antenna connection terminal 104, the second common terminal is connected to antenna connection terminal 105, the first selection terminal is connected to filter 17, and the second selection terminal is connected to filter 18.

Switch 46 can switch between (1) a mode in which signals in the first band are transmitted and received by antenna 2C and signals in the second band are transmitted and received by antenna 2D and (2) a mode in which signals in the first band are transmitted and received by antenna 2D and signals in the second band are transmitted and received by antenna 2C. Thus, filter 17 and filter 18 are connected to different antennas.

According to the above configuration of radio frequency circuit 1C according to this variation, a decrease in the S/N ratios of received signals in the first and second bands can be reduced, and signal distortion in RFIC 3 can be reduced. Thus, deterioration of reception sensitivity for the first band and the second band can be reduced.

### [2 Advantageous Effects and Others]

As described above, radio frequency circuit 1 according to the embodiment is configured to simultaneously transfer a signal in a first band and a signal in a second band different from the first band, and includes: filter 11 having a passband that includes at least a portion of the first band; power amplifier 21 connected to filter 11; filter 14 having a passband that includes at least a portion of the second band; low-noise amplifier 32 connected to filter 14; and band stop filter 15 connected to an output end of low-noise amplifier 32, and having a stopband that includes at least a portion of the first band.

According to this, band stop filter 15 is disposed on the output side of low-noise amplifier 32, and thus a leaky wave of a transmission signal in the first band transferred through the reception path for the second band can be reduced. Accordingly, a decrease in the S/N ratio of a received signal in the second band can be reduced, and signal distortion in RFIC 3 can be reduced. Thus, deterioration of reception sensitivity for the second band can be reduced. The filter structure of band stop filter 15 can be decreased in size and simplified as compared with a band pass filter having a passband that is the second band and an attenuation band that is other than the second band. Since band stop filter 15 is disposed on the output side of low-noise amplifier 32, a leaky wave of a transmission signal in the first band is reduced in a state in which a received signal in the second band is amplified by low-noise amplifier 32. Accordingly, a decrease in the S/N ratio of a received signal in the second band can be effectively reduced. Hence, as compared with a configuration in which the band stop filter is disposed on the input side of low-noise amplifier 32, deterioration of reception sensitivity for the second band can be effectively reduced.

As described above, radio frequency circuit 1A according to Variation 1 may include: filter 12 having a passband that includes at least a portion of a third band (or the first band); power amplifier 22 connected to filter 12; filter 13 having a passband that includes at least a portion of a fourth band (or the second band); low-noise amplifier 31 connected to filter 13; and band stop filter 16 connected to an output end of low-noise amplifier 31, and having a stopband that includes the third band (or the first band).

According to this, band stop filter 16 is disposed on the output side of low-noise amplifier 31, and thus a leaky wave of a transmission signal in the third band (or the first band) transferred through the reception path for the fourth band (or the second band) can be reduced. Accordingly, a decrease in the S/N ratio of a received signal in the fourth band (or the second band) can be reduced, and signal distortion in RFIC 3 can be reduced. Thus, deterioration of reception sensitivity for the fourth band (or the second band) can be reduced. The filter structure of band stop filter 16 can be decreased in size and simplified as compared with a band pass filter having a passband that is the fourth band (or the second band) and an attenuation band that is other than the fourth band (or the second band). Since band stop filter 16 is disposed on the output side of low-noise amplifier 31, a leaky wave of a transmission signal in the third band (or the first band) is reduced in a state in which a received signal in the fourth band (or the second band) is amplified by low-noise amplifier 31. Accordingly, a decrease in the S/N ratio of a received signal in the fourth band (or the second band) can be effectively reduced. Hence, as compared with a configuration in which the band stop filter is disposed on the input side of low-noise amplifier 31, deterioration of reception sensitivity for the fourth band (or the second band) can be effectively reduced.

For example, in radio frequency circuit 1B according to Variation 2 and radio frequency circuit 1C according to Variation 3, the first band and the second band may be bands for time division duplex (TDD), and radio frequency circuits 1B and 1C may each further include: power amplifiers 21 and 22; low-noise amplifiers 31 and 32; filters 17 and 18; switch 44 connected between (i) filter 17 and (ii) power amplifier 21 and low-noise amplifier 31, and configured to switch connection of filter 17 between power amplifier 21 and low-noise amplifier 31; and switch 45 connected between (i) filter 18 and (ii) power amplifier 22 and low-noise amplifier 32, and configured to switch connection of filter 18 between power amplifier 22 and low-noise amplifier 32.

According to this, under a condition that a signal in the first band for TDD and a signal in the second band for TDD are simultaneously transferred, band stop filter 15 is disposed on the output side of low-noise amplifier 32, and thus a leaky wave of a transmission signal in the first band transferred through the reception path for the second band can be reduced. Accordingly, a decrease in the S/N ratio of a received signal in the second band can be reduced, and signal distortion in RFIC 3 can be reduced. Thus, deterioration of reception sensitivity for the second band can be reduced.

For example, in radio frequency circuit 1B according to Variation 2 and radio frequency circuit 1C according to Variation 3 may each further include: band stop filter 16 connected to an output end of low-noise amplifier 31, and having a stopband that includes the second band.

According to this, band stop filter 16 is disposed on the output side of low-noise amplifier 31, and thus a leaky wave of a transmission signal in the second band transferred through the reception path for the first band can be reduced. Accordingly, a decrease in the S/N ratio of a received signal in the first band can be reduced, and signal distortion in RFIC 3 can be reduced. Thus, deterioration of reception sensitivity for the first band can be reduced.

For example, in radio frequency circuits 1, 1A, and 1C, the first filter and the second filter may be connected to different antennas.

According to this, a transmission path for the first band that includes the first filter and a reception path for the second band that includes the second filter can be highly isolated from each other. Thus, leakage of a transmission signal in the first band into the reception path for the second band that includes the second filter can be reduced.

For example, in radio frequency circuits 1, 1A, 1B, and 1C, the first band and the second band may be bands of at least 3 GHZ, and band stop filter 15 may include an inductor and a capacitor.

According to this, low-loss band stop filter 15 can be acquired by using a simplified filter structure.

For example, in radio frequency circuits 1, 1A, 1B, and 1C, the inductor and the capacitor may be integrated passive devices provided in or on a semiconductor substrate.

According to this, the size of band stop filter 15 can be reduced.

For example, radio frequency circuits 1, 1A, 1B, and 1C may each further include: a dielectric substrate in or on which the first filter, the second filter, power amplifier 21, and low-noise amplifier 32 are disposed, and the inductor and the capacitor may be provided in or on the dielectric substrate.

According to this, the sizes of radio frequency circuits 1, 1A, 1B, and 1C can be reduced.

For example, radio frequency circuits 1, 1A, 1B, and 1C may each further include: a dielectric substrate in or on which the first filter, the second filter, power amplifier 21, and low-noise amplifier 32 are disposed, the inductor and the capacitor may be surface-mount elements disposed in or on the dielectric substrate.

According to this, passing characteristics of band stop filter 15 can be improved by the inductor and the capacitor having high Q factors.

For example, in radio frequency circuits 1, 1A, 1B, and 1C, the first band may be band B40 for Long Term Evolution (LTE) or band n40 for 5th Generation New Radio (5G NR), and the second band may be band B41 for LTE or band n41 for 5G NR.

For example, in radio frequency circuits 1, 1A, 1B, and 1C, the first band may be one of band n77, n78, or n79 for 5th Generation New Radio (5G NR), and the second band may be a different one of band n77, n78, or n79 for 5G NR.

For example, in radio frequency circuits 1, 1A, 1B, and 1C, the first band may be one of a first frequency range defined by 5150 MHz to 5925 MHZ, a second frequency range defined by 5925 MHz to 7125 MHz, a third frequency range defined by 5925 MHz to 6425 MHz, or a fourth frequency range defined by 6425 MHz to 7125 MHz, and the second band may be a different one of the first frequency range, the second frequency range, the third frequency range, or the fourth frequency range.

For example, in radio frequency circuits 1 and 1A, one of the first band or the second band may be band B22 for Long Term Evolution (LTE).

For example, in radio frequency circuits 1 and 1A, the first band may be a band selected from among bands B1, B2, B3, B25, and B74 for Long Term Evolution (LTE) and bands n1, n2, n3, n25, and n74 for 5th Generation New Radio (5G NR), and the second band may be a different band selected from among bands B1, B2, B3, B25, and B74 for LTE and bands n1, n2, n3, n25, and n74 for 5G NR.

For example, in radio frequency circuits 1 and 1A, the first band may be a band selected from among bands B8, B12, B13, B20, B26, B71, and B85 for Long Term Evolution (LTE) and bands n8, n12, n13, n20, n26, n71, and n85 for 5th Generation New Radio (5G NR), and the second band may be a different band selected from among bands B8, B12, B13, B20, B26, B71, and B85 for LTE and bands n8, n12, n13, n20, n26, n71, and n85 for 5G NR.

Communication device 4 according to the present embodiment includes: RFIC 3 configured to process a radio frequency signal; and radio frequency circuit 1 configured to transfer the radio frequency signal between RFIC 3 and antennas 2A and 2B.

According to this, effects yielded by radio frequency circuit 1 can be yielded by communication device 4.

### OTHER EMBODIMENTS

Although the above has described the radio frequency circuits and the communication devices according to the embodiments and the variations, the radio frequency circuits and the communication devices according to the present disclosure are not limited to the above embodiments or variations. The present disclosure also encompasses another embodiment achieved by combining arbitrary elements in the above embodiments and variations, variations resulting from applying, to the above embodiments and variations, various modifications that may be conceived by those skilled in the art within a range that does not depart from the scope of the present disclosure, and various devices that each include the radio frequency circuit and the communication device.

For example, in the radio frequency circuits and the communication devices according to the embodiments and the variations, another circuit element and a line, for instance, may be provided between circuit elements and paths connecting signal paths, which are disclosed in the drawings.

The following shows features of the radio frequency circuits and the communication devices described based on the embodiments and the variations.

<1>

A radio frequency circuit configured to simultaneously transfer a signal in a first band and a signal in a second band different from the first band, the radio frequency circuit including:
a first filter having a passband that includes at least a portion of the first band;
a first power amplifier connected to the first filter;
a second filter having a passband that includes at least a portion of the second band;
a first low-noise amplifier connected to the second filter; and
a first band stop filter connected to an output end of the first low-noise amplifier, and having a stopband that includes at least a portion of the first band.

<2>

The radio frequency circuit according to <1>, further including:
a third filter having a passband that includes at least a portion of a third band;
a second power amplifier connected to the third filter;
a fourth filter having a passband that includes at least a portion of a fourth band;
a second low-noise amplifier connected to the fourth filter; and
a second band stop filter connected to an output end of the second low-noise amplifier, and having a stopband that includes the third band.

<3>

The radio frequency circuit according to <1>,
wherein the first band and the second band are bands for time division duplex, and
the radio frequency circuit further includes:
   a third power amplifier;
   a third low-noise amplifier;
   a first switch connected between (i) the first filter and (ii) the first power amplifier and the third low-noise amplifier, and configured to switch connection of the first filter between the first power amplifier and the third low-noise amplifier; and
   a second switch connected between (i) the second filter and (ii) the third power amplifier and the first low-noise amplifier, and configured to switch connection of the second filter between the third power amplifier and the first low-noise amplifier.

<4>

The radio frequency circuit according to <3>, further including:
a third band stop filter connected to an output end of the third low-noise amplifier, and having a stopband that includes the second band.

<5>

The radio frequency circuit according to any one of <1> to <4>,
wherein the first filter and the second filter are connected to different antennas.

<6>

The radio frequency circuit according to any one of <1> to <5>,
wherein the first band and the second band are bands of at least 3 GHZ, and
the first band stop filter includes an inductor and a capacitor.

<7>

The radio frequency circuit according to <6>,
wherein the inductor and the capacitor are integrated passive devices provided in or on a semiconductor substrate.

<8>

The radio frequency circuit according to <6>, further including:
a dielectric substrate in or on which the first filter, the second filter, the first power amplifier, and the first low-noise amplifier are disposed,
wherein the inductor and the capacitor are provided in or on the dielectric substrate.

<9>

The radio frequency circuit according to <6>, further including:
a dielectric substrate in or on which the first filter, the second filter, the first power amplifier, and the first low-noise amplifier are disposed,
wherein the inductor and the capacitor are surface-mount elements disposed in or on the dielectric substrate.

<10>

The radio frequency circuit according to <1> or <3>,
wherein the first band is band B40 for Long Term Evolution (LTE) or band n40 for 5th Generation New Radio (5G NR), and
the second band is band B41 for LTE or band n41 for 5G NR.

<11>

The radio frequency circuit according to <1> or <3>,
wherein the first band is one of band n77, n78, or n79 for 5th Generation New Radio (5G NR), and
the second band is a different one of band n77, n78, or n79 for 5G NR.

<12>

The radio frequency circuit according to <1> or <3>,
wherein the first band is one of a first frequency range defined by 5150 MHz to 5925 MHz, a second frequency range defined by 5925 MHz to 7125 MHz, a third frequency range defined by 5925 MHz to 6425 MHz, or a fourth frequency range defined by 6425 MHz to 7125 MHz, and
the second band is a different one of the first frequency range, the second frequency range, the third frequency range, or the fourth frequency range.

<13>

The radio frequency circuit according to <1> or <2>,
wherein one of the first band or the second band is band B22 for Long Term Evolution (LTE).

<14>

The radio frequency circuit according to <1> or <2>,
wherein the first band is a band selected from among bands B1, B2, B3, B25, and B74 for Long Term Evolution (LTE) and bands n1, n2, n3, n25, and n74 for 5th
the second band is a different band selected from among bands B1, B2, B3, B25, and B74 for LTE and bands n1, n2, n3, n25, and n74 for 5G NR.

<15>

The radio frequency circuit according to <1> or <2>,
wherein the first band is a band selected from among bands B8, B12, B13, B20, B26, B71, and B85 for Long Term Evolution (LTE) and bands n8, n12, n13, n20, n26, n71, and n85 for 5th Generation New Radio (5G NR), and
the second band is a different band selected from among bands B8, B12, B13, B20, B26, B71, and B85 for LTE and bands n8, n12, n13, n20, n26, n71, and n85 for 5G NR.

<16>

A communication device including:
a signal processing circuit configured to process a radio frequency signal; and
the radio frequency circuit according to any one of <1> to <15> configured to transfer the radio frequency signal between the signal processing circuit and an antenna.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones, as front-end circuits that support multiple bands and/or multiple modes.

1. A radio frequency circuit configured to simultaneously transfer a signal in a first band and a signal in a second band different from the first band, the radio frequency circuit comprising:
a first filter having a passband that includes at least a portion of the first band;
a first power amplifier connected to the first filter;
a second filter having a passband that includes at least a portion of the second band;
a first low-noise amplifier connected to the second filter; and
a first band stop filter connected to an output end of the first low-noise amplifier, and having a stopband that includes at least a portion of the first band.

2. The radio frequency circuit according to claim 1, further comprising:
a third filter having a passband that includes at least a portion of a third band;
a second power amplifier connected to the third filter;
a fourth filter having a passband that includes at least a portion of a fourth band;
a second low-noise amplifier connected to the fourth filter; and
a second band stop filter connected to an output end of the second low-noise amplifier, and having a stopband that includes the third band.

3. The radio frequency circuit according to claim 1,
wherein the first band and the second band are bands for time division duplex, and
the radio frequency circuit further comprises:
a third power amplifier;
a third low-noise amplifier;
a first switch connected between (i) the first filter and (ii) the first power amplifier and the third low-noise amplifier, and configured to switch connection of the first filter between the first power amplifier and the third low-noise amplifier; and
a second switch connected between (i) the second filter and (ii) the third power amplifier and the first low-noise amplifier, and configured to switch connection of the second filter between the third power amplifier and the first low-noise amplifier.

4. The radio frequency circuit according to claim 3, further comprising:
a third band stop filter connected to an output end of the third low-noise amplifier, and having a stopband that includes the second band.

5. The radio frequency circuit according to claim 1,
wherein the first filter and the second filter are connected to different antennas.

6. The radio frequency circuit according to claim 1,
wherein the first band and the second band are bands of at least 3 GHZ, and the first band stop filter includes an inductor and a capacitor.

7. The radio frequency circuit according to claim 6,
wherein the inductor and the capacitor are integrated passive devices provided in or on a semiconductor substrate.

8. The radio frequency circuit according to claim 6, further comprising:
a dielectric substrate in or on which the first filter, the second filter, the first power amplifier, and the first low-noise amplifier are disposed,
wherein the inductor and the capacitor are provided in or on the dielectric substrate.

9. The radio frequency circuit according to claim 6, further comprising:
a dielectric substrate in or on which the first filter, the second filter, the first power amplifier, and the first low-noise amplifier are disposed,
wherein the inductor and the capacitor are surface-mount elements disposed in or on the dielectric substrate.

10. The radio frequency circuit according to claim 1,
wherein the first band is band B40 for Long Term Evolution (LTE) or band n40 for 5th Generation New Radio (5G NR), and
the second band is band B41 for LTE or band n41 for 5G NR.

11. The radio frequency circuit according to claim 1,
wherein the first band is one of band n77, n78, or n79 for 5th Generation New Radio (5G NR), and
the second band is a different one of band n77, n78, or n79 for 5G NR.

12. The radio frequency circuit according to claim 1,
wherein the first band is one of a first frequency range defined by 5150 MHz to 5925 MHz, a second frequency range defined by 5925 MHz to 7125 MHz, a third frequency range defined by 5925 MHz to 6425 MHz, or a fourth frequency range defined by 6425 MHz to 7125 MHz, and
the second band is a different one of the first frequency range, the second frequency range, the third frequency range, or the fourth frequency range.

13. The radio frequency circuit according to claim 1,
wherein one of the first band or the second band is band B22 for Long Term Evolution (LTE).

14. The radio frequency circuit according to claim 1,
wherein the first band is a band selected from among bands B1, B2, B3, B25, and B74 for Long Term Evolution (LTE) and bands n1, n2, n3, n25, and n74 for 5th
the second band is a different band selected from among bands B1, B2, B3, B25, and B74 for LTE and bands n1, n2, n3, n25, and n74 for 5G NR.

15. The radio frequency circuit according to claim 1,
wherein the first band is a band selected from among bands B8, B12, B13, B20, B26, B71, and B85 for Long Term Evolution (LTE) and bands n8, n12, n13, n20, n26, n71, and n85 for 5th Generation New Radio (5G NR), and
the second band is a different band selected from among bands B8, B12, B13, B20, B26, B71, and B85 for LTE and bands n8, n12, n13, n20, n26, n71, and n85 for 5G NR.

16. A communication device comprising:
a signal processing circuit configured to process a radio frequency signal; and
the radio frequency circuit according to claim 1 configured to transfer the radio frequency signal between the signal processing circuit and an antenna.
